(19) United States
(12) Patent Application Publication
(10) Pub. No.: US 2005/0095846 A1
(43) Pub. Date: May 5, 2005

(54) System and method for defect free conductor deposition on substrates

(76) Inventor: Bulent M. Basol, Manhattan Beach, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/979,341

(22) Filed: Nov. 1, 2004

Related U.S. Application Data
(60) Provisional application No. 60/516,091, filed on Oct. 31, 2003.

(51) Int. Cl. H01L 21/4763

(52) U.S. Cl. 438/637

(57) ABSTRACT

A system and method for depositing a defect-free conductor on semiconductor substrates having features and seed layers with defective regions. A repair layer is deposited over the seed layer and the defective regions in a deposition module within a housing. The repair layer can be deposited by atomic layer deposition or chemical vapor deposition. A conductive material is then electroplated over the seed layer to fill the features and form a defect-free conductive layer over the top surface of the substrate. The electroplating is performed in another deposition module within the housing.

### RELATED APPLICATIONS

This application claims priority to U.S. Provisional Application No. 60/516,091, filed Oct. 31, 2003.

### FIELD

The present invention generally relates to semiconductor processing technologies and, more particularly, to an electrodepositing process and system with seed layer repair capability.

### BACKGROUND

Conventional semiconductor devices generally include a semiconductor substrate, which is typically a silicon substrate, and a plurality of sequentially formed dielectric interlayers, such as silicon dioxide, and conductive paths or interconnects made of conductive materials. The interconnects are usually formed by filling a conductive material in trenches that are etched into the dielectric interlayers. In an integrated circuit, multiple levels of interconnect networks laterally extend with respect to the substrate surface. The interconnects formed in different layers can be electrically connected with each other using vias or contacts. A metallization process can be used to fill such features, i.e., via openings, trenches, pads or contacts with a conductive material.

Copper and copper alloys have recently received considerable attention as interconnect materials because of their superior electromigration and low resistivity characteristics. The preferred method of copper metallization is electroplating. Before the electroplating process, the substrate is first coated with a barrier layer. Typical barrier materials generally include tungsten, tantalum, titanium, their alloys, and their nitrides. The barrier layer coats the substrate to ensure good adhesion and acts as a barrier material to prevent diffusion of the copper into the dielectric layers and into the semiconductor devices. Next, a seed layer, which is often a copper layer, is deposited on the barrier layer. The seed layer forms a conductive material base for copper film growth during subsequent copper deposition. The copper seed layers for copper interconnects are typically deposited by physical vapor deposition (PVD) techniques.

The most common problem associated with such techniques is poor step coverage, which may give rise to discontinuities in the seed layer and related defects, especially within narrow openings or features with highest aspect ratios. The seed layer thickness at the lower portions or on the side-walls of the high aspect ratio vias and trenches may be very low, typically less than 10 Angstrom (A), or the seed layer at such locations may be discontinuous. These thin portions of the seed layer may contain large amounts of oxide phases that are not stable in plating solutions. During the subsequent copper deposition process, such defective areas (thin or discontinuous portions of the seed layer) cause unwanted voids resulting in inadequately filled vias and trenches.

FIG. 1A exemplifies the problem of poor sidewall coverage in an exemplary feature such as a via 10 formed in a substrate layer 12, such as a dielectric layer, using a conventional process, such as the one described above. As shown in FIG. 1A, the via 10 is coated with a barrier layer 14 and a seed layer 16 having defective areas 18. As shown in FIG. 1B, when the via 10 is filled with the copper metal 20 in a subsequent step, a void 22 is formed because of the discontinuity in the seed layer 16 at the defective areas 18. The discontinuity disrupts growth at that location and also interferes with the bottom-up growth front coming from the bottom of the via.

Defects in seed layers are expected to become an important issue as the seed layer thickness is reduced and the aspect ratios of features are increased. One method used to fix discontinuities in seed layers is electroless deposition of a thin copper layer on the wafer, which is already coated with a seed layer. Typically, the seed layer is deposited by standard PVD approaches. A thin electroless layer coats the thin regions as well as the discontinuous regions of the seed layer, thereby eliminating defective areas by repairing such discontinuities. Electroless plating is a wet processing technique that can be negatively impacted itself by defect formation due to various factors such as micro bubble formation on the substrate during deposition.

To this end, there is a need for techniques for fixing defective seed layers before wafers are plated with a conductor, such as copper.

### SUMMARY

In accordance with one aspect of the invention, a method is provided of void-free filling of a conductive material into a feature formed in a surface of a substrate. The substrate has a seed layer formed over the surface and interior walls of the features. The method comprises placing the substrate in an atomic layer deposition module, forming a repair layer over the seed layer in the atomic layer deposition module, moving the substrate to an electrochemical deposition chamber after forming the repair layer, and depositing a conductive material over the repair layer to fill the feature and to form a conductive layer on the surface of the substrate.

In accordance with another aspect of the invention, a system is provided for processing a workpiece by seed layer repair and electrodeposition. The workpiece has a seed layer having defective regions over a surface of the workpiece and interior walls of a feature formed in the surface. The system includes an atomic layer deposition module in a housing. The atomic layer deposition module is configured to deposit a repair layer over the seed layer and the defective regions. The system also includes at least one electrochemical mechanical deposition module in the housing. The at least one electrochemical mechanical deposition module is configured to deposit a conductive material over the repair layer to fill the feature and coat the surface of the workpiece with a layer of the conductive material.

In accordance with yet another aspect of the invention, a method is provided of void-free filling of a feature on a semiconductor substrate having a seed layer over a surface of the substrate. The seed layer has at least one defect. The method comprises placing the substrate in a first deposition module within a cluster tool, forming a repair layer over the seed layer and the at least one defect in the deposition module, moving the substrate to a second deposition module within the cluster tool after forming the repair layer, and depositing a conductive material over the repair layer to fill the feature and to form a conductive layer on the surface of the substrate.

### BRIEF DESCRIPTION OF THE DRAWINGS

These and other aspects of the invention will be readily apparent to the skilled artisan in view of the description below, the appended claims, and from the drawings, which are intended to illustrate and not to limit the invention, and wherein:

FIG. 1A is a schematic side view of a feature lined with a copper seed layer including defects;

FIG. 1B is a schematic side view of the feature shown in FIG. 1A after being filled with copper using a prior art deposition process;

FIG. 2A is a schematic side view of the feature shown in FIG. 1A wherein the seed layer and the defects have been coated with a thin repair layer using an ALD process;

FIG. 2B is an enlarged schematic side view of a conductive repair layer on a defective region of the feature shown in FIG. 2A;

FIG. 3 is a schematic side view of the feature shown in FIG. 2A wherein defect-free copper is filled using an electrodeposition process; and

FIG. 4 is a schematic top plan view of a system including an ALD module and an electrodeposition module.

### DETAILED DESCRIPTION

The following detailed description of the preferred embodiments and methods presents a description of certain specific embodiments to assist in understanding the claims. However, one may practice the present invention in a multitude of different embodiments and methods as defined and covered by the claims.

It will be appreciated that the apparatuses may vary as to configuration and as to details of the parts, and that the methods may vary as to the specific steps and sequence, without departing from the basic concepts as disclosed herein.

As will be described below, the present invention provides a method and a system using chemical vapor deposition (CVD), atomic layer deposition (ALD), and related chemical techniques for fixing defective seed layers. CVD and ALD are presently used to deposit thin layers of barrier and seed layers on substrates.

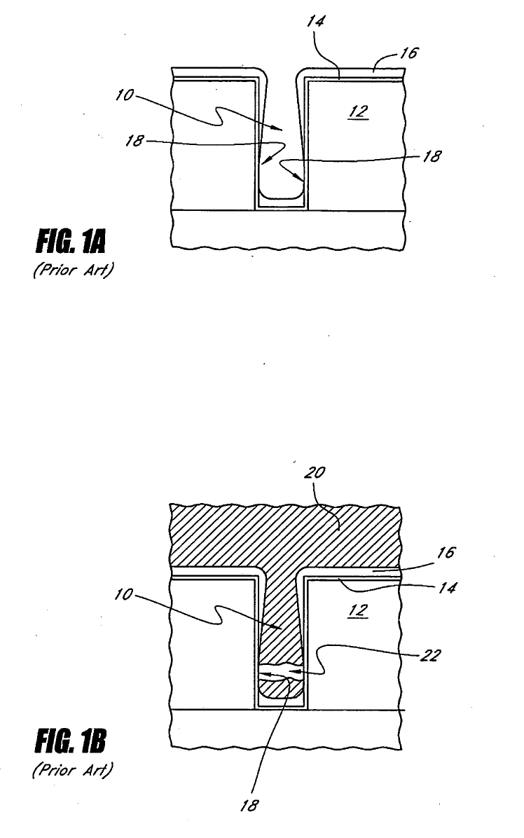

The advantage of ALD is its near-perfect conformal coating property. For example, a copper layer deposited by an ALD process would coat the whole substrate surface, including the high aspect ratio vias very uniformly. The thickness of the copper layer deposited by ALD on the top surface of the substrate would be the same as the thickness of the copper layer on the via bottom and walls. Therefore, defects such as the discontinuities depicted in FIG. 1A, would not be expected to form from ALD of copper unless there is contamination on the barrier layer surface that disrupts growth of the copper. The disadvantage of the ALD approach is its low throughput. ALD forms a monolayer of film during each of its cycles. Each cycle includes introducing the deposition gasses, initiating reaction, and pumping out the gasses. Therefore, it takes many ALD cycles to form a seed layer of conductive film. For example, deposition of a 500 Å thick seed layer may take more than 15 minutes.

Preferred embodiments of the present invention use the benefit of the ALD method, which is its near-perfect conformal deposition, and avoid its disadvantage, which is its low throughput. According to an embodiment, an ALD chamber is integrated with an electroplating chamber within a common housing of a single process tool. According to this embodiment, the ALD process is used, not necessarily for depositing the entire seed layer, but for repairing a previously deposited seed layer. The previously deposited seed layer may be deposited by any suitable method, such as standard PVD techniques.

To repair the seed layer, a conductive film having a thickness preferably in the range of about only 5-50 Å, and more preferably in the range of 10-20 Å, is deposited, and the deposition is preferably highly conformal. The ALD process allows deposition of a conductive film with such conformality at a reasonably fast rate because the conductive film thickness is relatively small. According to another embodiment, CVD can be carried out to repair a defective or discontinuous seed layer coated over a barrier layer the same way ALD is used.

Substrates with repaired seed layers may be subsequently plated, preferably by an electroplating process. The electroplating process is preferably performed using either an electrochemical deposition (ECD) process or an electrochemical mechanical deposition (ECMD) process within an integrated system. It is be understood that, in this integrated system, the ALD or CVD process is performed within the same tool, having a common housing, as the subsequent electroplating process. The ECMD process, as compared to the ECD process, produces a planar conductive layer. Descriptions of various ECMD methods and apparatuses can be found in the following patents and pending applications: U.S. Pat. No. 6,176,992, entitled “Method and Apparatus for Electrochemical Mechanical Deposition,” U.S. Pat. No. 6,354,116, entitled “Plating Method and Apparatus that Creates a Differential Between Additive Disposed on a Top Surface and a Cavity Surface of a Workpiece Using an External Influence,” U.S. Pat. No. 6,471,847, entitled “Method for Forming Electrical Contact with a Semiconductor Substrate,” and U.S. Pat. No. 6,610,190, entitled “Method and Apparatus for Electrodeposition of Uniform Film with Minimal Edge Exclusion on Substrate.” The entire disclosures of all of the foregoing patents are hereby incorporated herein by reference.

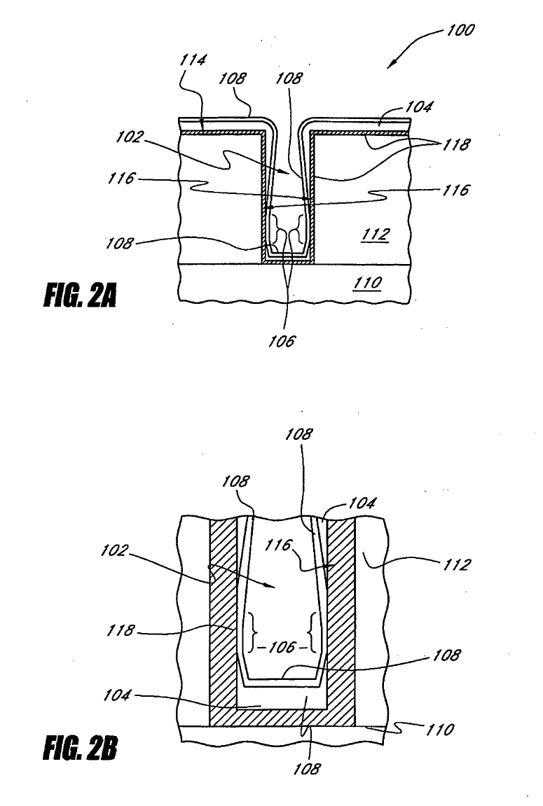

Reference will now be made to the drawings in which like numerals refer to like parts throughout. FIGS. 2A through 2B show an exemplary seed layer repair process according to a preferred embodiment. FIG. 2A is a schematic side view of a substrate 100 including a feature 102, such as a via or a narrow trench. In order to exemplify the repair process according to this embodiment, a seed layer 104 is shown in FIG. 2A with exemplary defective (or discontinuous) regions 106. As will be described more fully below, a repair layer 108 is used to repair the defect in the defective region 106. It will be understood, of course, that the repair process can be conducted without regard to whether defects actually exist in the seed layer 104. Rather, mere risk or probability of such defects, for the selected seed layer deposition conditions, is sufficient to conduct the repair process. Such risk is high due to selection of a seed deposition process that is economical in combination with ALD seed repair.

As shown in FIG. 2A, the substrate 100 is a multi-layer structure over a semiconductor wafer 110. The feature 102 is formed in a dielectric layer 112 deposited over the surface of the wafer 110. Further, there may be intervening elements between the wafer 110 and the bottom of feature 102. The dielectric layer 112 has a top surface 114 and the feature 102 has sidewalls 116. The side walls 116 of the feature 102 as well as the top surface 114 of the dielectric layer are typically coated with a barrier layer 118 or a glue layer such as a tantalum (Ta) and/or a tantalum nitride (TaN) layer. Well-known processes in the art, including, but not limited to, PVD and ALD, may be used to deposit the barrier layer 118 or glue layer. One such process is described in U.S. Pat. No. 6,727,169, the entire disclosure of which is hereby incorporated herein by reference.

Next, a seed layer 104, which is a thin film of conductive material is deposited over the barrier layer 118 to allow for a subsequent copper plating process. The seed layer 118 may preferably be a thin film of copper, but that other suitable conductive materials may be used for the seed layer and the subsequently deposited layer of conductive material. The seed layer 118 preferably has a thickness in the range of about 50-500 Å.

In the figures, the seed layer 104 thickness at the top portion of the feature 102 is highly exaggerated to better illustrate the defective regions 106 and the repair layer 108. In this embodiment, the defective regions 106 are regions where the seed layer 104 is discontinuous and portions of the barrier layer are exposed. Those skilled in the art will appreciate that, alternatively, defect regions could be regions where the barrier layer is not exposed, but the seed layer 104 thickness is extremely low, for example, less than 10 Å.

In the illustrated embodiment, the seed layer 104 has defective regions 106 to be repaired using the process of this embodiment. Although the defective regions 106, in the example shown in FIG. 2A, are on the sidewalls 116 of the feature 102, as is understood they can be anywhere on the seed layer 104.

As shown in FIG. 2A and in FIG. 2B, the repair layer 108 is deposited such that it preferably conformally covers the seed layer 104 and the defective regions 106. The repair layer 108 is a thin layer of conductive material, which can be deposited using the ALD process in a seed layer repair step of this embodiment. In a preferred embodiment, the repair layer 108 is formed of a thin layer of copper. The terms “discontinuous region” and “defective region” refer to either openings in the seed layer 104 or undesirably thin regions of the seed layer 104, which are repaired by the repair layer 108 of preferred embodiments. An ALD process is described in U.S. Pat. No. 6,727,169, the entire disclosure of which is incorporated herein by reference. Examples of ALD systems are described in U.S. Pat. No. 6,562,140, the entire disclosure of which is incorporated herein by reference.

Although in this embodiment the repair layer of the present invention is applied onto the seed layer, the reversal of the process steps is also possible. Accordingly, a repair layer may be formed on the barrier layer prior to depositing a seed layer. The combination of the seed layer and repair layer forms a continuous bi-layer on the substrate. The repair layer of the bi-layer of the present invention provides conductive continuity of the seed layer whether or not deposited before the seed layer deposition or after the seed layer deposition. Such deposited repair layer repairs defects and improves continuity especially in small width features. For example, the repair layers deposited with the process of the present invention advantageously provides continuity inside the features having width less than 0.1 micron. For the subsequent electrochemical process, ALD deposited repair layer is mainly responsible for the conductivity and conductive continuity in such small features while the conductivity of the surface is mainly provided by the thicker seed layer. It should be noted that although the preferred repair layer material is copper in the illustrated embodiment, other conductors, such as W, Ru, Pt, etc., may also be used as repair layers.

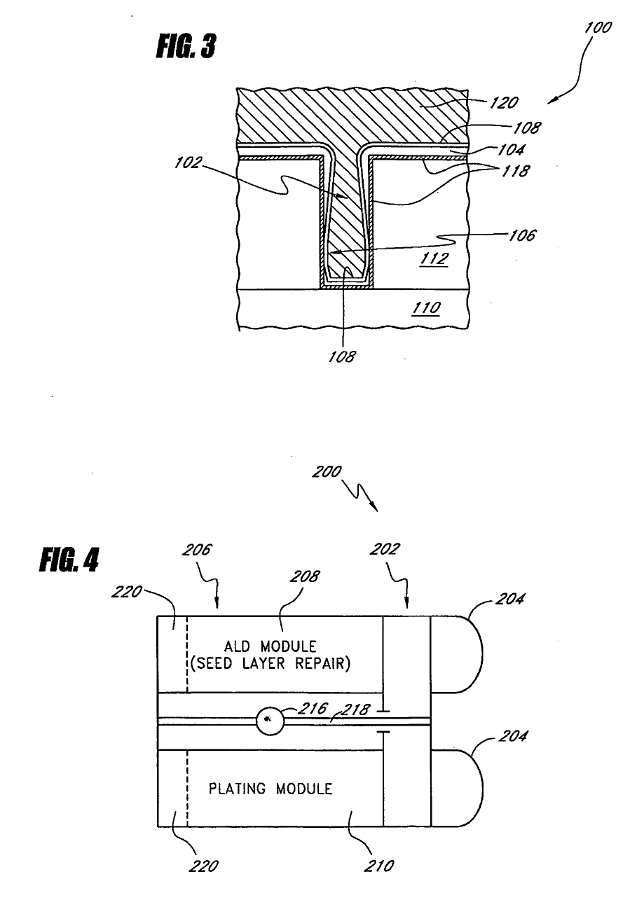

As shown in FIG. 3, following the seed layer repair step of this embodiment, in an electrodeposition step, the substrate 100 is plated with a conductive material 120. Preferably, the substrate 100 is plated with the conductive material 120 by using an electrochemical deposition process, such as ECD or ECMD. In a preferred embodiment, the conductive material 120 is copper. During the electrodeposition step, a layer of conductive material 120 is deposited over the repair layer 108 and fills the feature 102 in a bottom-up fashion with conductive material 120. In this respect, if the repair layer 108 is formed of copper, for example, the layer of conductive material 120 is also preferably formed of copper. The repair layer may also be formed of materials, such as Ru and Pt, because copper plates well on such materials. The continuous conductive layer established by the repair layer 108 in the defective regions 106 eliminates the void problem described above in the Background of the Invention section.

An example of an integrated system 200 that can be used to practice an embodiment is schematically shown in FIG. 4. As shown in FIG. 4, the system 200 is a single process tool that may have a load/unload section 202 for loading and unloading wafer cassettes or boxes 204, and a process section 206. The load/unload section 202 may comprise a shared load/unload platform for multiple wafer boxes 204.

Wafers from the boxes 204 may be delivered to the process section 206 using one or more robots 216, which may be located either in the process section 206 or the load/unload section 202, or in both sections. It will be appreciated that the substrate 100 may be transported through the system 200 by one or more robots 216. For example, in the illustrated embodiment, a shared robot 216 is capable of moving the substrate 100 around the system between any of the process modules 208, 210, 212, 214 and the wafer boxes 204. In the illustrated embodiment of FIG. 4, the robot 216 may slide along a track 218 to move around within the system 200. In alternative embodiments, the system 200 may have more than one robot 216, each situated in a different location to access different modules and wafer boxes.

In a preferred embodiment, the modules 208, 210 of the system 200 are all within a common housing such that the substrate 100 is not exposed to the atmosphere when it is transported between modules, thereby reducing the danger of contamination, as there is a higher purity level behind the load/unload section 202 relative to the clean room atmosphere. It is understood that the system 200 is a cluster tool.

The process section 206 has at least one seed layer repair module 208 and at least one plating module 210. The seed layer repair module 208 can be, for example, either an ALD or CVD module, and the plating module can be, for example, either an ECD or ECMD module. In the illustrated embodiment of FIG. 4, the system 200 includes an ALD module for seed layer repair 208 and an electrochemical deposition module for plating 210 on the same platform within a single process tool, which increases throughput and prevents contamination problems which may occur when substrates are transported between non-integrated repair and plating modules, thereby exposing them to the clean room atmosphere.

It should be noted that other modules, such as cleaners, driers, annealers, edge copper removers, PVD modules and CMP modules may also be added to the system 200 of FIG. 4. For example, the system 200 may include, in a common housing with the modules 208, 210, a cleaning module for cleaning and rinsing the substrate 100. As shown in FIG. 4, cleaning modules 220 may be integrated within one or both of the modules 208, 210. U.S. patent application Ser. No. 10/041,029, entitled Vertically Configured Chamber Used for Multiple Processes, filed Dec. 28, 2001, the entire disclosure of which is hereby incorporated herein by reference, describes a vertically configured plating and cleaning chamber system. In another embodiment, a cleaning module 220 may be a separate module in the system 200, as shown schematically. Preferably, the substrate 100 is cleaned in situ prior to deposition of the repair layer 108 by ALD or CVD. The system may include a PVD module to deposit a seed layer before or after depositing a repair layer in the ALD module to form the above mentioned bi-layer in the same system.

Accordingly, referring to FIGS. 2A, 2B, 3 and 4, in one embodiment, the substrate 100 having the defective regions 106 in the seed layer 104 is first delivered to the ALD module 208 for the seed layer repair step. In other embodiments, the substrate 100 is delivered to a CVD module for the seed layer repair step. Once the repair layer 108 is coated on the defective regions 106 and on the seed layer 104 as a continuous layer, the substrate 100 is delivered to the plating module to perform the electrodepositon step as described above.

Alternatively, the seed repair ALD module may be integrated with the seed deposition module, such as a PVD module, so that before or after the ALD deposition, the substrate may be delivered to a PVD module for depositing the seed layer. Such processed substrate coated with both a seed layer and repair layer is then delivered to the plating module. Once the electrodeposition is complete, the substrate 100 may be taken back to wafer box 204 after cleaning, drying, and edge copper removal in in situ cleaning module 220 or a vertically integrated cleaning module (if any). Annealing may also be performed on the same platform before returning the substrates 100 to their boxes 204.

Although various preferred embodiments have been described in detail above, those skilled in the art will readily appreciate that the present invention extends beyond the specifically disclosed embodiments to other alternative embodiments and/or uses of the invention and obvious modification thereof without materially departing from the novel teachings and advantages of this invention. Thus, it is intended that the scope of the present invention herein disclosed should not be limited by the particular disclosed embodiments described above, but should be determined only by a fair reading of the claims that follow.

1. A method of void-free filling of a conductive material into a feature formed in a surface of a substrate having a seed layer formed over the surface and interior walls of the features, the method comprising:
placing the substrate in an atomic layer deposition module;
forming a repair layer over the seed layer in the atomic layer deposition module;
moving the substrate to an electrochemical deposition chamber after forming the repair layer; and
depositing a conductive material over the repair layer to fill the feature and to form a conductive layer on the surface of the substrate.

2. The method of claim 1, wherein the repair layer has a thickness of about 5-50 Å

3. The method of claim 1, wherein the seed layer has at least one defect.

4. The method of claim 3, wherein the at least one defect is at least one discontinuity in the seed layer.

5. The method of claim 3, wherein the at least one defect is at least one thin portion in the seed layer, the thin portion having a thickness of less than 10 Å.

6. The method of claim 1, wherein depositing the conductive material is performed by electroplating.

7. The method of claim 1, wherein the conductive material is copper.

8. The method of claim 1, wherein the seed layer is deposited in a PVD module.

9. A system for processing a workpiece by seed layer repair and electrodeposition, wherein the workpiece has a seed layer over a surface of the workpiece and interior walls of a feature formed in the surface, the seed layer having defective regions, the system comprising:
an atomic layer deposition module in a housing, the atomic layer deposition module configured to deposit a repair layer over the seed layer and the defective regions; and
at least one electrodeposition module in the housing, the at least one electrodeposition module configured to deposit a conductive material over the repair layer to fill the feature and coat the surface of the workpiece with a layer of the conductive material.

10. The system of claim 9, further comprising a cleaning module within the housing, the cleaning module configured to clean the workpiece after deposition of the conductive material.

11. The system of claim 10, wherein the cleaning module is integrated into the electrodeposition module.

12. The system of claim 9, wherein the atomic layer deposition module is configured to deposit a repair layer formed of copper.

13. The system of claim 9, wherein the defective regions are discontinuities in the seed layer.

14. The system of claim 9, wherein the defective regions are thin portions in the seed layer.

15. The system of claim 9, further comprising a PVD module configured to deposit the seed layer.

16. A method of void-free filling of a feature on a semiconductor substrate having a seed layer over a surface of the substrate, the seed layer having at least one defect, the method comprising:
placing the substrate in a first deposition module within a cluster tool;
forming a repair layer over the seed layer and the at least one defect in the deposition module;
moving the substrate to a second deposition module within the cluster tool after forming the repair layer; and
depositing a conductive material over the repair layer to fill the feature and to form a conductive layer on the surface of the substrate.

17. The method of claim 16, wherein the first deposition module is an atomic layer deposition module.

18. The method of claim 16, wherein the first deposition module is a chemical vapor deposition module.

19. The method of claim 16, wherein the second deposition module is an electroplating module.

20. The method of claim 16, wherein the conductive material is copper.

21. The method of claim 16, wherein the repair layer has a thickness of about 5-50 Å.

22. A method of void-free filling of a conductive material into a feature formed in a surface of a substrate, the method comprising:
forming a bi-layer including a repair layer and a seed layer on the surface of the substrate, wherein the repair layer is deposited by ALD and the seed layer is deposited by PVD;
moving the substrate to an electrochemical deposition chamber; and
depositing the conductive material onto the bi-layer to fill the feature and to form a conductive layer on the surface of the substrate.

23. The method of claim 22, wherein the repair layer is deposited before the seed layer.

24. The method of claim 22, wherein the seed layer is deposited before the repair layer.
